(19) United States
(12) Patent Application Publication
(10) Pub. No.: US 2020/0159042 A1
(43) Pub. Date: May 21, 2020

(54) OPHTHALMIC LENS IDENTIFICATION USING ULTRASOUND

(71) Applicant: Johnson & Johnson Vision Care, Inc., Jacksonville, FL (US)

(72) Inventors: Donald Scott Langford, Melbourne, FL (US); Adam Toner, Jacksonville, FL (US)

(21) Appl. No.: 16/197,298

(22) Filed: Nov. 20, 2018

(51) Int. Cl. G02C 7/02; G02C 7/08; H01L 27/24; H04B 11/00

(52) U.S. Cl. CPC G02C 7/024; G02C 7/083; G02C 7/04; H04B 11/00; G02C 7/022; H01L 27/24

(57) ABSTRACT

An ophthalmic lens having an electronic system is described herein for providing an identification in response to a signal or inquiry and/or receiving an identification tag. The ophthalmic lenses include at least one ultrasound module having at least one transducer such as a transmit transducer or a piezoelectric transducer. The ophthalmic lens further includes an identification module for generating an identification in response to a signal and powering the ultrasound module to propagate at least one sound pressure wave embodying the identification. In at least one embodiment, the identification data is encoded after manufacture of the device. The ophthalmic lens may be a contact lens or an intraocular lens.

### BACKGROUND OF THE INVENTION

### 1. Field of the Invention

The present invention relates to a powered or electronic ophthalmic lens, and more particularly, to a powered or electronic ophthalmic lens having an identification module to provide an identification in response to an inquiry and/or be assigned an identification number by an external device.

### 2. Discussion of the Related Art

As electronic devices continue to be miniaturized, it is becoming increasingly more likely to create wearable or embeddable microelectronic devices for a variety of uses. Such uses may include monitoring aspects of body chemistry, administering controlled dosages of medications or therapeutic agents via various mechanisms, including automatically, in response to measurements, or in response to external control signals, and augmenting the performance of organs or tissues. Examples of such devices include glucose infusion pumps, pacemakers, defibrillators, ventricular assist devices and neurostimulators. A new, particularly useful field of application is in ophthalmic wearable lenses and contact lenses. For example, a wearable lens may incorporate a lens assembly having an electronically adjustable focus to augment or enhance performance of the eye. In another example, either with or without adjustable focus, a wearable contact lens may incorporate electronic sensors to detect concentrations of particular chemicals in the precorneal (tear) film. The use of embedded electronics in a lens assembly introduces a potential requirement for communication with the electronics, for a method of powering and/or re-energizing the electronics, for interconnecting the electronics, for internal and external sensing and/or monitoring, and for control of the electronics and the overall function of the lens.

The human eye has the ability to discern millions of colors, adjust easily to shifting light conditions, and transmit signals or information to the brain at a rate exceeding that of a high-speed internet connection. Lenses, such as contact lenses and intraocular lenses, currently are utilized to correct vision defects such as myopia (nearsightedness), hyperopia (farsightedness), presbyopia and astigmatism. However, properly designed lenses incorporating additional components may be utilized to enhance vision as well as to correct vision defects.

Conventional contact lenses are polymeric structures with specific shapes to correct various vision problems as briefly set forth above. To achieve enhanced functionality, various circuits and components have to be integrated into these polymeric structures. For example, control circuits, microprocessors, communication devices, power supplies, sensors, actuators, light-emitting diodes, and miniature antennas may be integrated into contact lenses via custom-built optoelectronic components to not only correct vision, but to enhance vision as well as provide additional functionality as is explained herein. Electronic and/or powered ophthalmic lenses may be designed to provide enhanced vision via zoom-in and zoom-out capabilities, or just simply modifying the refractive capabilities of the lenses. Electronic and/or powered contact lenses may be designed to enhance color and resolution.

The proper combination of devices could yield potentially unlimited functionality; however, there are a number of difficulties associated with the incorporation of extra components on a piece of optical-grade polymer. In general, it is difficult to manufacture such components directly on the lens for a number of reasons, as well as mounting and interconnecting planar devices on a non-planar surface. It is also difficult to manufacture to scale. The components to be placed on or in the lens need to be miniaturized and integrated onto just 1.5 square centimeters of a transparent polymer while protecting the components from the liquid environment on the eye.

It is also difficult to make a contact lens comfortable and safe for the wearer with the added thickness of additional components.

In addition, because of the complexity of the functionality associated with a powered lens and the high level of interaction between all of the components comprising a powered lens, there is a need to coordinate and control the overall operation of the electronics and optics comprising a powered ophthalmic lens. Accordingly, there is a need for a system to control the operation of all of the other components and provide identification for the ophthalmic lens that is safe, low-cost, and reliable, has a low rate of power consumption and is scalable for incorporation into an ophthalmic lens. Accordingly, there exists a need for a means and method for providing and/or assigning an identification to ophthalmic lenses

There are several scenarios where there is a need for powered contact lenses to communicate during normal operation. Methods of detecting and changing lens state for presbyopia, commonly referred to as accommodation, may require the state of the left and right eye to be shared to determine if the lens focus should be changed. In each case, the independent state of each eye must be communicated so that the system controller can determine the required state of the variable lens actuator. There are other cases where it may enhance the user experience if the lens state (e.g., focus state) is changed in a coordinated fashion.

### SUMMARY OF THE INVENTION

Lens-to-lens communication may take place wirelessly. There are at least three approaches to communicate lens-to-lens: photonic (light), radio frequency (RF) and ultrasound communication. Communication using light is difficult as the power consumption associated with generating photonic signals sufficiently powerful to overcome ambient interference may be prohibitive for the lens power source. RF signal generation may be possible but challenging. Higher RF frequency signals are required to operate with antennas that are sized to fit within a typical contact lens application. Generation of higher frequency signals typically require more power due to less efficient sources. RF energy is absorbed by human tissue thus reducing power at the receiver. Ultrasound communication is desirable as the sound spectrum is unregulated and there are few background ultrasound signals. The required ultrasound frequency is orders of magnitude lower than required RF frequency for a similar application. The power level required to generate ultrasound signals is therefore lower than RF signals for a similar application. Ultrasound energy has significantly less absorption in the human body. Due to the lower absorption, the allowed power levels for safe ultrasound energy operation in the body are orders of magnitude higher than RF energy limits.

In at least one embodiment, an ophthalmic lens configured to provide an identification tag using ultrasound where the ophthalmic lens includes: an ultrasound module including at least one processor and at least one transducer, the ultrasound module configured to propagate and receive sound pressure waves; a power source; an identification module in electrical communication with the power source and the ultrasound module, the identification module having data representing an identification tag; and wherein the ultrasound transducer is configured to receive from the identification module the data to control output of the at least one transducer.

In a further embodiment, the ophthalmic lens further includes a non-volatile memory having the data. In a further embodiment, the non-volatile memory is at least one of an electrically erasable programmable memory, a one-time programmable memory, a magneto resistive running application memory, a ferro-magnetic running application memory, a flash memory, a read-only memory, and/or a polymer thin film ferroelectric memory.

In a further embodiment to the above embodiments, the identification module further includes an envelope detector configured to gate the identification module; and an amplitude modulator configured to generate a digital signal embodying an identification tag.

In a further embodiment to the above embodiment, the at least one transducer includes a piezoelectric transducer; and the power source includes an energy harvester module in electrical communication with the piezoelectric transducer, the energy harvester module having a voltage rectifier, and a power storage device in electrical communication with the voltage rectifier. Further to the previous embodiment, the power storage device includes a capacitor, a battery, and/or an energy harvester module in electrical communication with the ultrasound module, and the energy harvester module is configured to receive at least one sound pressure wave having a sound pressure level greater than 1 millipascal. In a further embodiment to the embodiments of the preceding paragraphs, the power source includes an energy harvester module; and the identification module includes an envelope detector in electrical communication with the energy harvester module, an amplitude modulator in electrical communication with the envelope detector, a non-volatile memory in electrical communication with the envelope detector and the amplitude modulator; and wherein the ultrasound module is configured to receive from the amplitude modulator of the identification module the data to control output of the at least one transducer.

In a further embodiment to the above embodiments, the ultrasound module is configured to propagate the sound pressure wave at a frequency above 20 kilohertz. In a further embodiment to the above embodiments, the ultrasound module is configured to receive sound pressure waves at a frequency greater than 20 kilohertz.

In at least one embodiment, a method for providing an identification tag using an ophthalmic lens system including a transducer, an energy harvester, an identification module in electrical communication with the energy harvester module, and a driver module in electrical communication with the energy harvester and the identification module, the method including: receiving an ultrasound pressure wave embodying a read signal from an external source by the ultrasound transducer; generating a voltage by the energy harvester in response to the received ultrasound pressure wave; powering the identification module with the generated voltage; transmitting a data signal representing an identification tag for the ophthalmic lens by the identification module to the driver module; and driving with the driver module the transducer to propagate a sound pressure wave embodying a message communicating the identification tag.

Further to the previous embodiment, the the identification module further includes a pulse detector and a non-volatile memory configured to store and retrieve data, the method further including: propagating an ultrasound pressure wave embodying an identification tag by an identification generator; receiving the ultrasound pressure wave embodying the identification tag at the transducer of the ophthalmic lens; generating a voltage by the energy harvester in response to the received ultrasound pressure wave embodying the identification tag; powering the identification module in response to the received ultrasound pressure wave embodying the identification tag; serially decoding the identification tag by the pulse detector of the identification module; and encoding the identification tag to the non-volatile memory by the identification module.

In at least one embodiment, a method for assigning an identification tag using an ophthalmic lens system including an ultrasound transducer, an energy harvester having a rectifier and a capacitor, an identification module including a pulse detector, a pattern modulator and a non-volatile memory configured to store and retrieve data in electrical communication with the energy harvester module, and a driver module in electrical communication with the energy harvester and the identification module, the method including: propagating an ultrasound pressure wave embodying an identification tag by an identification generator; receiving the ultrasound pressure wave embodying the identification tag at the ultrasound transducer of the ophthalmic lens; generating a voltage by the energy harvester in response to the received ultrasound pressure wave; powering the identification module in response to the received ultrasound pressure wave; serially decoding the identification tag by the pulse detector of the identification module; and encoding the identification tag to the non-volatile memory by the identification module.

Further to any of the above embodiments, the ophthalmic lens is a contact lens. In an alternative embodiment to any of the embodiments in the above paragraphs, the ophthalmic lens is an intraocular lens. Further to any of the above embodiments, the identification tag includes a unique identifier for the ophthalmic lens.

Further to any of the embodiments above, a message sent by the system controller of the first ophthalmic lens uses a predefined protocol. Further to any of the embodiments above, the message sent by the system controller of the first ophthalmic lens includes instructions for the second ophthalmic lens to perform a predefined function. Further to any of the embodiments above, the message sent by the system controller of the first ophthalmic lens includes sensor readings from at least one sensor on the first ophthalmic lens.

### BRIEF DESCRIPTION OF THE DRAWINGS

The foregoing and other features and advantages of the invention will be apparent from the following, more particular description of preferred embodiments of the invention, as illustrated in the accompanying drawings.

FIG. 1 illustrates a contact lens having at least one ultrasound module and an identification module in accordance with at least one embodiment of the present invention.

FIG. 2 illustrates a contact lens having at least one ultrasound module, a system controller having a register, an identification module, and an actuator in accordance with at least one embodiment of the present invention.

FIG. 3 illustrates an ultrasound module in accordance with at least one embodiment of the present invention.

FIG. 4 illustrates an ultrasound module with one transducer and a multiplexer in accordance with at least one embodiment of the present invention.

FIG. 5 illustrates an ultrasound module with a charge pump and an envelope detector in accordance with at least one embodiment of the present invention.

FIG. 6 illustrates an ultrasound module with one transducer and a multiplexer in accordance with at least one embodiment of the present invention.

FIG. 7 illustrates an ultrasound module with one transducer and a multiplexer in accordance with at least one embodiment of the present invention.

FIG. 8 illustrates an ultrasound module with a plurality of transmit/receive transducer pairs or transceiver transducers in accordance with at least one embodiment of the present invention.

FIG. 9 illustrates one embodiment of the ultrasound identification circuit having an ultrasound module, an energy harvester module and an identification module in accordance with at least one embodiment of the present invention.

FIG. 10 illustrates one embodiment of the ultrasound identification circuit having a non-volatile memory configured to read data and write data thereto in accordance with at least one embodiment of the present invention.

FIG. 11 illustrates a diagrammatic representation of an electronic insert, including a transducer, for a powered contact lens in accordance with at least one embodiment of the present invention.

FIG. 12 illustrates a method for providing an identification tag in response to a read signal in accordance with at least one embodiment of the present invention.

FIG. 13 illustrates a method for assigning an identification tag to a contact lens in accordance with at least one embodiment of the present invention.

### DETAILED DESCRIPTION OF THE EMBODIMENTS

Conventional contact lenses are polymeric structures with specific shapes to correct various vision problems as briefly set forth above. To achieve enhanced functionality, various circuits and components may be integrated into these polymeric structures. For example, control circuits, microprocessors, communication devices, power supplies, sensors, ultrasound modules, and miniature antennas may be integrated into contact lenses via custom-built optoelectronic components to not only correct vision, but to enhance vision as well as provide additional functionality as is explained herein. Electronic and/or powered ophthalmic lenses may be designed to provide enhanced vision via zoom-in and zoom-out capabilities, or just simply modifying the refractive capabilities of the lenses. Electronic and/or powered ophthalmic lenses may be designed to enhance color and resolution. In addition, ultrasound modules built into the lenses may be utilized to provide/receive an identification tag from an external device, to detect blink patterns and/or objects along with communicate with other lenses or external devices. In at least one embodiment, the identification tag is an alphanumeric or binary identification for the ophthalmic lens. In further embodiments, the identification tag includes information that assigns the ophthalmic lens as 1) a left ophthalmic lens or right ophthalmic lens and/or 2) a master ophthalmic lens or a servant ophthalmic lens. In further embodiments, the identification tag includes code or instructions for the operation of the receiving ophthalmic lens.

The powered or electronic ophthalmic lens in at least one embodiment includes the necessary elements to monitor the wearer with or without elements to correct and/or enhance the vision of the wearer with one or more of the above described vision defects or otherwise perform a useful ophthalmic function. The electronic ophthalmic lens may have a variable-focus optic lens, an assembled front optic embedded into an ophthalmic lens or just simply embedding electronics without a lens for any suitable functionality. The electronic lens of the present invention may be incorporated into any number of ophthalmic lenses as described above. An ophthalmic lens includes a contact lens and/or an intraocular lens. However, for ease of explanation, the disclosure will focus on an electronic contact lens intended for single-use daily disposability.

The present invention may be employed in a powered ophthalmic lens or powered contact lens having an electronic system, which actuates a variable-focus optic or any other device or devices configured to implement any number of numerous functions that may be performed. The electronic system includes one or more batteries or other power sources, power management circuitry, one or more sensors, clock generation circuitry, control algorithms and circuitry, and lens driver circuitry. The complexity of these components may vary depending on the required or desired functionality of the lens.

Control of an electronic or a powered ophthalmic lens may be accomplished through a manually operated external device that communicates with the lens through radio frequency and/or ultrasonic communication, such as a hand-held remote unit, a phone, a storage container, spectacles, glasses, or a cleaning box. For example, an external device may wirelessly communicate using ultrasound with the powered lens based upon manual input from the wearer. Alternatively, control of the powered ophthalmic lens may be accomplished via feedback or control signals directly from the wearer.

Because of the complexity of the functionality associated with a powered lens and the high level of interaction between all of the components comprising a powered lens, there is a need to coordinate and control the overall operation of the electronics and optics comprising a powered ophthalmic lens. Accordingly, there is a need for a system controller to control the operation of all of the other components and provide communication between the contact lenses that is low-cost and reliable, has a low rate of power consumption, and is scalable for incorporation into an ophthalmic lens.

In at least one embodiment, a sound pressure wave, which is produced at a transmit ultrasound transducer, propagates from the contact lens into the field of view. In at least one embodiment, the sound pressure wave includes a burst(s) or multiple sound pressure waves.

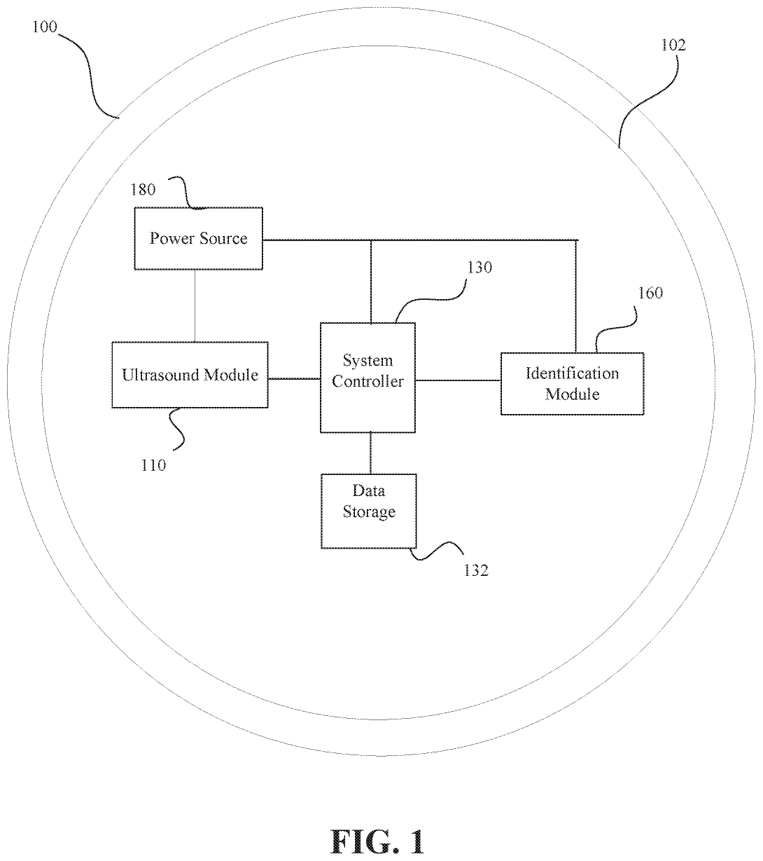

FIGS. 1-7 illustrate different embodiments according to the invention that include a system controller 130 connected to a timing circuit 140, which may be omitted in some embodiments although illustrated, and an ultrasound module (collectively referred to as 110) that are on a contact lens 100. The ultrasound module 110 may take a variety of forms including distinct transmit and receive transducers or a shared transmit/receive transducer. Depending on a particular implementation, there may be multiple ultrasound modules 110 present on the contact lens to facilitate particular functionality for the contact lens or alternatively multiple transducers connected to one or more ultrasound modules. Many of the figures include an actuator 150 as part of the system with the actuator 150 being representative of, for example, lens accommodation components, data collection components, data monitoring components, and/or functional components such as an alarm.

The system controller 130 in at least one embodiment uses at least one predetermined threshold or template for interpreting the output of the ultrasound module 110. In another embodiment, the system controller 130 makes use of at least one template (or pattern) to which a series of outputs of the ultrasound module 110 are compared against to determine whether the template has been satisfied, for example based on a match to the pattern and/or a threshold being met, exceeded or less than resulting in the template being satisfied. In at least one embodiment, the problem template includes only at least one threshold. In an alternative embodiment, both thresholds and patterns are used by the system controller 130 to interpret a received series of sound pressure waves. In at least one embodiment as illustrated in FIG. 1, the system controller 130 is in electrical communication with a data storage 132 that stores the threshold(s) and/or template(s). In at least one embodiment, a plurality of templates includes any combination of patterns and thresholds. Examples of data storage 132 include memory such as persistent or non-volatile memory, volatile memory, and buffer memory, a register(s), a cache(s), programmable read-only memory (PROM), programmable erasable memory, magneto resistive random access memory (RAM), ferro-electric RAM, flash memory, and polymer thin film ferroelectric memory. In an alternative embodiment, the output(s) of the ultrasound module 110 to the system controller 130 is converted by the system controller 130 into data (or a signal(s)) for control of the actuator 150. In an alternative embodiment, the system controller 130 interprets the output of the ultrasound module 110 using a predefined protocol.

FIG. 1 illustrates a system on a contact lens 100 having an electro-active region 102 with an ultrasound module 110, a system controller 130, an identification module 160, and a power source 180. In at least one further embodiment, the electro-active region 102 includes an electronics ring around the contact lens 100 on which the electronics are located. The ultrasound module 110 in at least one embodiment has two-way communication with the system controller 130. In at least one embodiment, the identification module 160 is configured to output a signal corresponding to an identification tag in response to a read signal received at the ultrasound transducer 116, and in such an embodiment the identification module 160 may be connected to the ultrasound module 110.

In at least one embodiment, the ultrasound module 110 includes a transducer that provides an output that is both a signal and voltage to power at least a portion of the contact lens 100. Examples of a simplified ultrasound module 110 are discussed in connection with later figures.

FIG. 1 also illustrates a power source 180, which supplies power for numerous components in the system. The power may be supplied from a battery, energy harvester, or other suitable means as is known to one of ordinary skill in the art. Essentially, any type of power source 180 may be utilized to provide reliable power for all other components of the system. In an alternative embodiment, communication functionality is provided by an energy harvester that acts as the receiver for the time signal, for example in an alternative embodiment, the energy harvester is a photovoltaic cell (in at least a contact lens embodiment), a photodiode (in at least a contact lens embodiment), or a radio frequency (RF) receiver, which receives both power and a time-base signal (or indication). In a further alternative embodiment, the energy harvester is an inductive charger, in which power is transferred in addition to data such as RFID. In one or more of these alternative embodiments, the time signal could be inherent in the harvested energy, for example N*60 Hz in inductive charging or lighting.

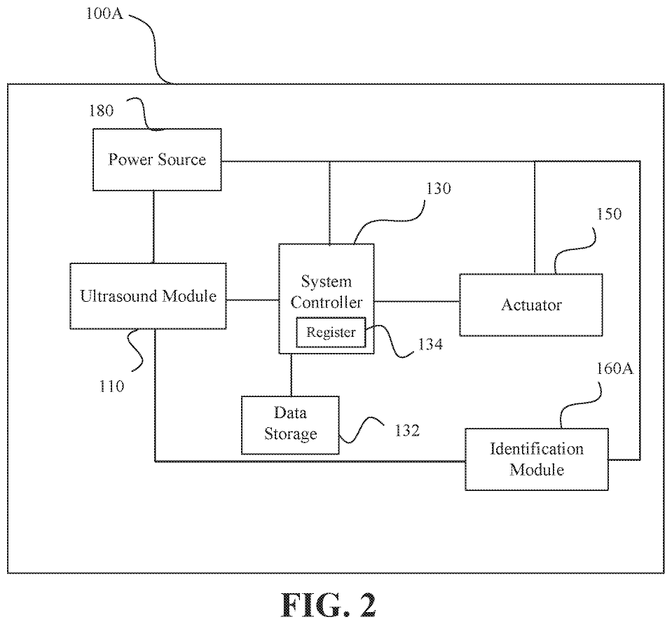

In at least one alternative embodiment as illustrated in FIG. 2, the system further includes an actuator 150 configured to receive an output from the system controller 130A. The actuator 150 is omitted from one or more of the illustrated embodiments in this disclosure.

The actuator 150 may include any suitable device for implementing a specific function based upon a received command signal from the system controller 130A. For example, if a set of data samples matches a template, the system controller 130A may enable the actuator 150 to change focus of the contact lens, provide an alert to the wearer such as a light (or light array) to pulse a light or cause a physical wave to pulsate into the wearer's retina (or alternatively across the lens), or to log data regarding the state of the wearer. Further examples of the actuator 150 acting as an alert mechanism include an electrical device; a mechanical device including, for example, piezoelectric devices, transducers, vibrational devices, chemical release devices with examples including the release of chemicals to cause an itching, irritation or burning sensation, and acoustic devices; a transducer providing optic zone modification of an optic zone of the contact lens such as modifying the focus and/or percentage of light transmission through the lens; a magnetic device; an electromagnetic device; a thermal device; an optical coloration mechanism with or without liquid crystal, prisms, fiber optics, and/or light tubes to, for example, provide an optic modification and/or direct light towards the retina; an electrical device such as an electrical stimulator to provide a mild retinal stimulation or to stimulate at least one of a corneal surface and one or more sensory nerves of the cornea; or any combination thereof. In an alternative embodiment, the actuator 150 sends an alert to an external device using, for example the ultrasound module 110. The actuator 150 receives a signal from the system controller 130A in addition to power from the power source 180 and produces some action based on the signal from the system controller 130A. For example, if the output signal from the system controller 130A occurs during one operation state, then the actuator 150 may alert the wearer that a medical condition has arisen or the contact lens is ending/nearing its useful life and/defective. In an alternative embodiment, the actuator 150 delivers a pharmaceutical product to the wearer in response to an instruction from the system controller 130A. In an alternative embodiment, the system controller 130A outputs the signal during another operation state, then the actuator 150 will record the information in memory for later retrieval. In a still further alternative embodiment, the signal will cause the actuator to alarm and store information. In an alternative embodiment, the system controller 130A stores the data in the memory (e.g., data storage 132 in other embodiments) associated with the system controller 130A and does not use the actuator 150 for data storage and in at least one embodiment, the actuator 150 is omitted. As set forth above, the powered lens of the present invention may provide various functionality; accordingly, one or more actuators may be variously configured to implement the functionality.

In at least one alternative embodiment, which is also illustrated in FIG. 2, the contact lens 100A includes a system controller 130A having a register 134 for storing data samples from the ultrasound module 110. In a further embodiment, there is an individual register for each ultrasound module 110 and/or a receiving transducer present on the contact lens 100A. The use of a register 134 in at least one embodiment allows for the comparison of data with prior data, a threshold, a preset value, a calibrated value, a target processing value, or a template with or without a mask. In an alternative embodiment, other data storage is used instead of a register(s). In an alternative embodiment, the register 134 is part of the data storage 132. FIG. 2 also illustrates how the identification module 160A is connected directly with the ultrasound module 110A to allow for communication about the identification tag for the contact lens 100A to occur without powering the rest of the components.

Based on this disclosure, it should be appreciated that in addition to the presence of the ultrasound module 110 on the contact lens 100 that additional sensors may be included as part of the contact lens to monitor characteristics of the eye and/or the lens. In at least one embodiment, at least a portion of the actuator 150 is consolidated with the system controller 130.

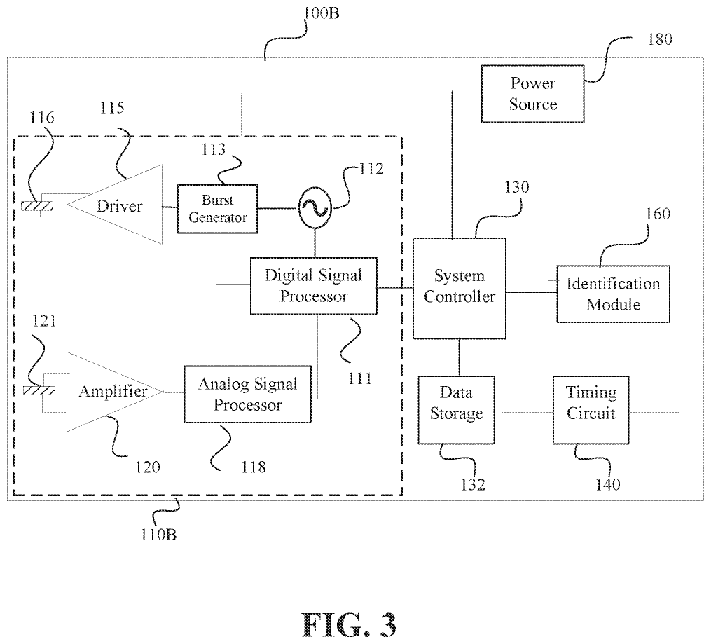

FIGS. 3-8 illustrate different ultrasound modules that illustrate different transmit paths and receive paths examples of paths that facilitate transmitting and receiving sound pressure waves from one or more transducers 116, 121 that start or end with a processor 111 and/or the system controller 130 depending on the example embodiment.

FIG. 3 illustrates a contact lens 100B that includes an ultrasound module 110B having distinct transmit and receive sides to the ultrasound module 110B. The illustrated ultrasound module 110B includes a digital signal processor 111, an oscillator 112, a burst generator 113, a transmit driver 115, a transmit ultrasound transducer 116, an analog signal processor 118, a receive amplifier 120, and a receive ultrasound transducer 121. In at least one embodiment, the burst generator 113 produces a series of 1's and 0's, which in at least one embodiment may be used to facilitate communication with another lens and/or an external device. In at least one embodiment, the burst generator 113 incorporates a unique identifier for the contact lens based on the amplitude, the frequency, the length, and/or the code modulation of the signal. In a further embodiment, the unique identifier is provided by the system controller 130, the digital signal processor 111, the oscillator 112, and/or the burst generator 113. A similar use of unique identifier may be used with other embodiments in this disclosure. In at least one alternative embodiment for the ultrasound module 110C, the digital signal processor 111 is combined with the system controller 130. In another alternative embodiment, the analog signal processor 118 is combined with the digital signal processor 111 and/or replaced with an analog-to-digital convertor as illustrated in a later figure. These two alternative embodiments may be combined to provide a further alternative embodiment.

The digital signal processor 111 receives a control signal from the system controller 130. In at least one embodiment, the digital signal processor 111 includes a resettable counter and a time-to-digital convertor and transmit/receive sequencing controls. The oscillator 112 in at least one embodiment is a switched oscillator. In at least one embodiment, the frequency of the oscillator 112 is programmable through a preset oscillator value, the system controller or external interface (e.g., an interface with an external device). The frequency can be tuned using a reference oscillator and an external interface. In at least one further embodiment, the frequency is set or tuned to a value that minimizes transmit and receive electrical power and allows the transmit ultrasound transducer 116 to produce a pressure sound wave that will have maximum amplitude at the receiver input. In a more particular embodiment, the oscillator 112 is a programmable frequency oscillator such as a current starved ring oscillator where the current and the capacitance control the oscillation frequency where the frequency can be altered by changing the current supplied to the oscillator. In at least one embodiment, the wavelength of the sound pressure wave is tuned based on the dimensions of the transducer used. In a further embodiment, the oscillator 112 varies over time for optimal transmission characteristics. In a still further embodiment, the frequency is calibrated using a reference frequency provided through an external interface and an automatic frequency control (AFC) circuit. The frequency is preset with the AFC tuning it. The frequency can be directly set through the serial interface, which is accessed through the external communications link.

The output voltage of the burst generator 113 may be level shifted to the appropriate value for the transmit driver 115 and the transmit ultrasound transducer 116. An example of the transmit ultrasound transducer 116 is a piezoelectric device which converts applied burst voltage to a sound pressure wave. In at least one embodiment, the sound pressure wave includes a burst(s) or multiple sound pressure waves. In a further embodiment, the transmit ultrasound transducer 116 is made of any piezoelectric material that is compatible with the power source and the physical properties of the contact lens. Another example of a transducer is a polyvinylidene fluoride or polyvinylidene difluoride (PVDF) film. The sound pressure wave produced by the transmit ultrasound transducer 116 propagates from the contact lens 100 into the field of view.

The receive amplifier 120 and the analog signal processor 118 in at least one embodiment are turned on with the oscillator 112 or turned on after a predetermined delay after the oscillator 112 is started. When there is a predetermined delay, power for contact lens operation may be lowered during the period of delay. In an embodiment where the receive amplifier 120 and the analog signal processor 118 are started with the oscillator 112, the receive amplifier 120 will receive an output from the receive ultrasound transducer 121 proximate to when the sound pressure wave is output by the transmit ultrasound transducer 116. This output from the receive ultrasound transducer 121 can be used to reset the counter in the digital signal processor 111. In a further embodiment, the detection of the transmit sound pressure wave can be used as an indicator that a true transmit signal has been generated.

A sound pressure wave received by the receive ultrasound transducer 121 will produce a voltage signal with a frequency, an amplitude and/or a burst length properties related to the transmitted sound pressure wave. The voltage signal is amplified by the receive amplifier 120 before being sent to the analog signal processor 118, which in an alternative embodiment to embodiments having the receive amplifier 120 and the signal processor 118 are combined into a signal processor. The analog signal processor 118 may include, but is not limited to, frequency selective filtering, envelope detection, integration, level comparison and/or analog-to-digital conversion. Based on this disclosure, it should be appreciated that these functions may be separated into individual blocks with some examples being illustrated in later figures. The analog signal processor 118 produces a received signal that represents the received sound pressure wave at the receive ultrasound transducer 121, which in implementation will have a slight delay. The received signal is passed from the analog signal processor 118 to the digital signal processor 111. In at least one embodiment, the digital signal processor 111 interprets the received signal for a message from, for example, the other contact lens or an external device. The resulting output from the digital signal processor 111 is provided to the system controller 130.

The embodiment illustrated in FIG. 3 also adds an optional timing circuit 140 to the system components illustrated in FIG. 1. The timing circuit 140 provides a clock function for operation of the contact lens. As illustrated the timing circuit 140 is connected to the system controller 130. In at least one embodiment, the timing circuit 140 drives the system controller 130 to send a signal to the ultrasound module 110B to perform a function based on a sampling time interval, which in at least one embodiment is variable based on the output from the ultrasound module 110B to the system controller 130. In an alternative embodiment, the timing circuit 140 is part of the system controller 130.

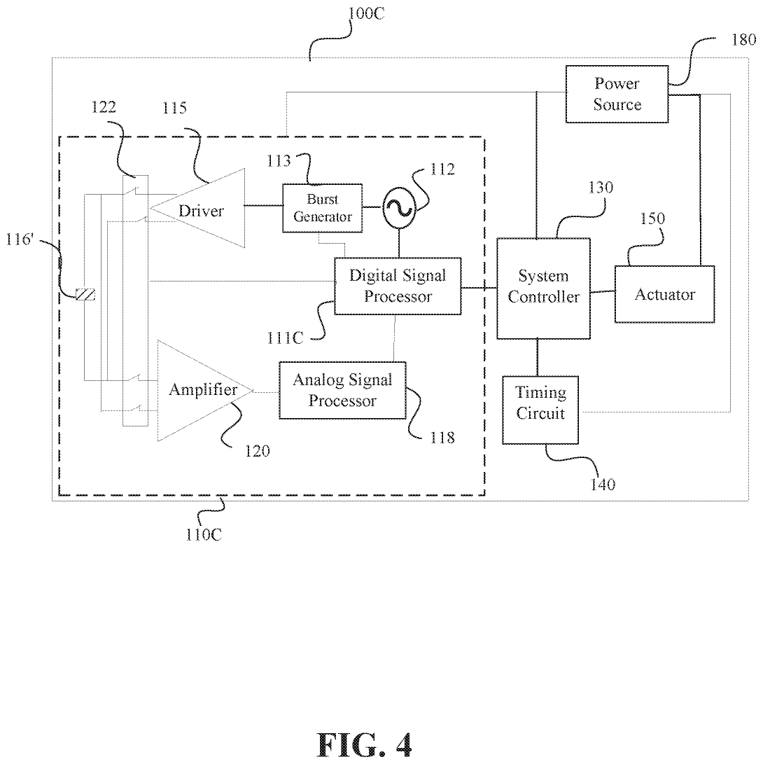

FIG. 4 illustrates a contact lens 100C with an ultrasound module 110C. The illustrated ultrasound module 110C includes one ultrasound transducer 116′ that is shared by the transmit and receive sides (or paths). The single ultrasound transducer 116′ is multiplexed between transmit and receive operation through use of a switch 122. The digital signal processor 111C uses the output of the burst generator 113 to switch the transducer 116′ to transmit mode by connecting the transmit driver 115 to the transducer 116′. When the burst is completed, then the digital signal processor 111C switches the switch 122 to the receive mode by connecting the receive amplifier 120 to the transducer 116′. One advantage to this configuration is that the transducer area is reduced from two transducers to one transducer, but a drawback to this configuration is that a short time of flight may not be detected or if the ultrasound module is being used for communication, then a received communication may be missed during a transmission or vice versa. As with the previous embodiment, a delay may be imposed after transmission before the receive amplifier 120 is powered. The remaining components of the illustrated embodiment remain the same from the prior embodiment.

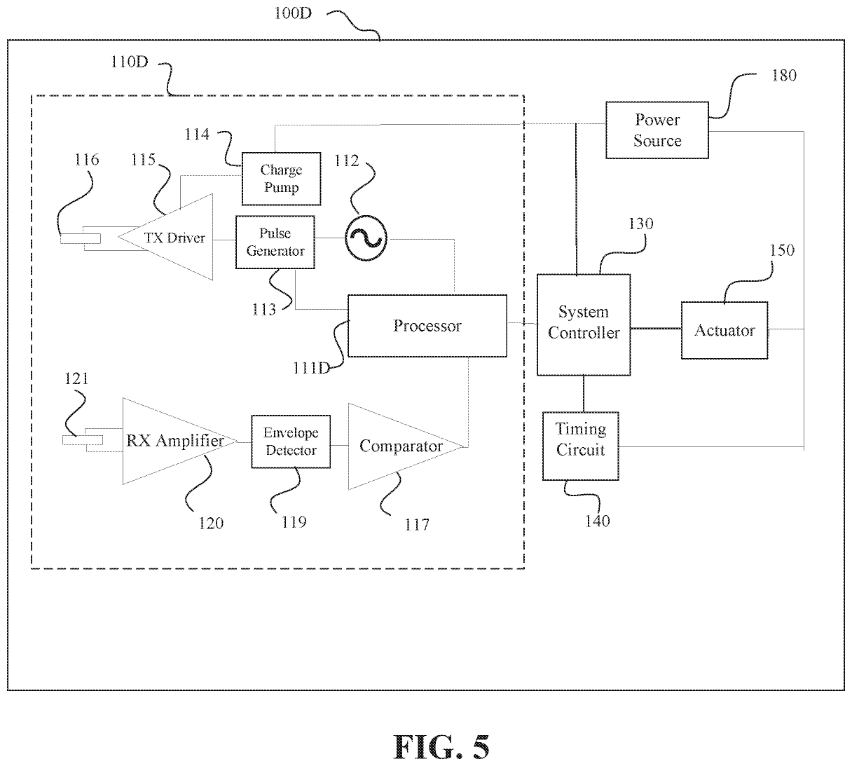

FIG. 5 illustrates a contact lens 100D with an ultrasound module 110D. The illustrated ultrasound module 110D includes a processor 111D, the oscillator 112, the pulse generator 113, a charge pump 114, the transmit driver 115, the transmit ultrasound transducer 116, a comparator 117, an envelope detector 119, the receive amplifier 120, and the receive ultrasound transducer 121. The charge pump 114 is electrically connected to the power source 180 and to the transmit driver 115, which provides a voltage to the transmit ultrasound transducer 116 to create the sound pressure wave to be emitted by the transducer 116. In at least one embodiment, the transmit driver 115 includes an inverter or an H-bridge, and in further embodiments includes an output driver circuit. In at least one embodiment, the charge pump 114 increases the voltage through the relationship between charge and capacitance with voltage by increasing the charge on a capacitance component(s) (e.g., a capacitor). The voltage output from the charge pump 114, in at least one embodiment, is used as the supply voltage to the transmit driver 115. The transmit driver 115 switches between the output of the charge pump 114 and ground in an alternating fashion in response to the input from the pulse generator 113 to produce an alternating voltage. The alternating voltage is applied by the driver 115 to polarize the material of the transducer 116 in one direction and then the other direction to create a mechanical stress causing the material to be displaced in a specific direction (i.e. the direction the transducer is facing). The displacement of the transducer material coupled with the shape and the size of the transducer produce the sound pressure wave. Thus, the larger the applied voltage is to the transducer, the larger the stress and thus the larger the displacement and associated sound pressure wave.

The charge pump 114 is also electrically connected to the processor 111D, which controls operation of the charge pump 114 in at least one embodiment to minimize power consumption by the system by, for example turning off the oscillator 112, the pulse generator 113, and/or the charge pump 114 at times when the ultrasound module 110D does not need to propagate a sound pressure wave. The envelope detector 119 turns the high-frequency output of the receive ultrasound transducer 121 into a new signal that provides an envelope signal representative of the original output signal to be provided to the comparator 117. This illustrated embodiment has the advantage of simplifying the analysis of the output of the receive ultrasound transducer 121 to determine if a particular threshold has been met for the contact lens 100D to perform a function. The comparator 117 provides an output to the processor 111D, which is in electrical communication with the system controller 130.

FIG. 6 illustrates a contact lens 100E with an ultrasound module 110E. The illustrated ultrasound module 110E includes a digital signal processor 111E, the oscillator 112, the pulse generator 113, the charge pump 114, the transmit driver 115, the transmit/receive ultrasound transducer 116′, an analog-to-digital converter (ADC) 118E, an envelope detector 119, the receive amplifier 120, and the switch 122. The ADC 118E converts the output from the envelope detector 119 into a digital signal for the digital signal processor 111E.

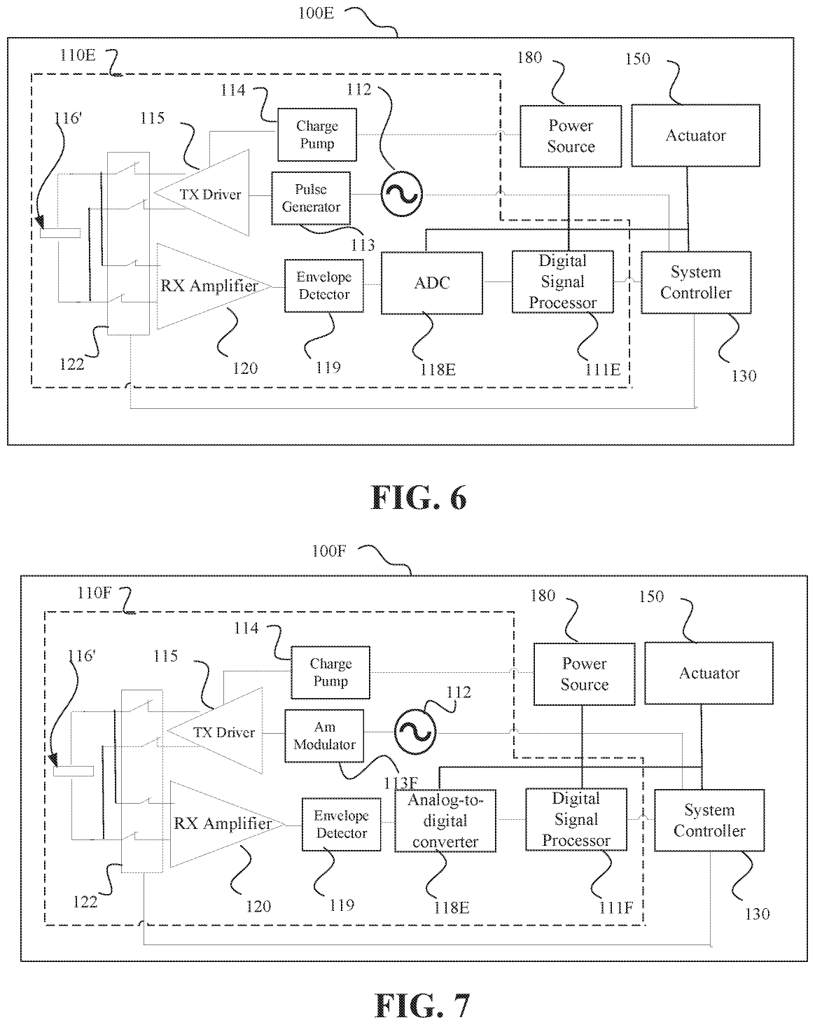

FIG. 7 illustrates a contact lens 100F with an ultrasound module 110F. The illustrated ultrasound module 110F includes a digital signal processor 111F, the oscillator 112, an amplitude modulation (AM) modulator 113F, the charge pump 114, the transmit driver 115 such as a transmit amplifier, the transmit/receive ultrasound transducer 116′, an analog-to-digital converter (ADC) 118E, an envelope detector 119, the receive ultrasound transducer 121, and the switch 122. In the illustrated embodiment, the charge pump 114, the AM modulator 113F and transmit driver 115 act as the level shifter and the burst generator. The AM modulator 113F in this embodiment is controlled by the digital signal processor 111F. The circuit works where the oscillator signal is provided to the AM modulator 113F, which in at least one embodiment is an AND gate, and the digital signal processor 111F provides a second clock at a frequency much lower than the oscillator frequency. The output of the circuit is then a sequence of pulses that occur during the positive cycle of the lower frequency. The transmit driver 115 has the appropriate gain to output the modulated signal at the charge pump voltage thus providing level shifting.

Based on the disclosure connected to FIGS. 5-7, one of ordinary skill in the art should appreciate that the different ultrasound module configurations and transducer/switch configurations may be interchanged and mixed together in different combinations.

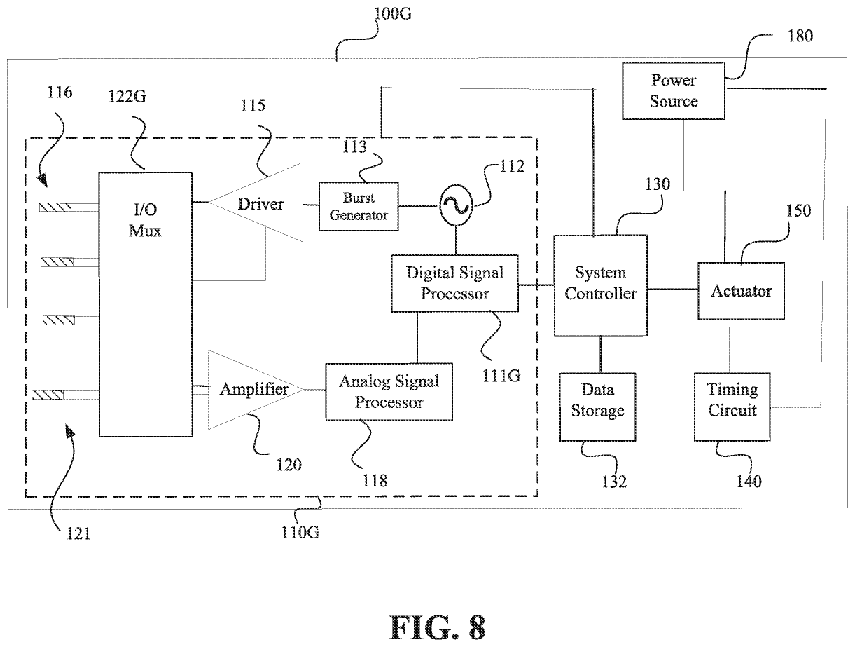

In an alternative embodiment illustrated in FIG. 8, the contact lens 100G has one ultrasound module 110G having a plurality of transducers 116, 121 and an I/O multiplexer (mux) 122G attaching the transducers 116, 121 to the ultrasound module components discussed in the above embodiments. FIG. 8 illustrates the inclusion of the digital signal processor 111G, the oscillator 112, the burst generator 113, the driver 115, the amplifier 120, and the analog signal processor 118. In an alternative embodiment, these ultrasound module components may be replaced by components from the other described ultrasound module embodiments including using just the transmit or receive paths of those embodiments. An advantage of this configuration is that it reduces the power requirements and weight considerations by eliminating duplicative components and allowing the ultrasound module to drive multiple transmit transducers and to receive analog signals from multiple receive transducers.

In at least one embodiment where the contact lens includes rotational stability features, then the number of ultrasound modules is one. The angle at which the transducer is relative to the electronics ring may be more severe such that a perpendicular line drawn from the transducer would intersect with the bridge (or just below the bridge) of most wearers of the intended population for the contact lens.

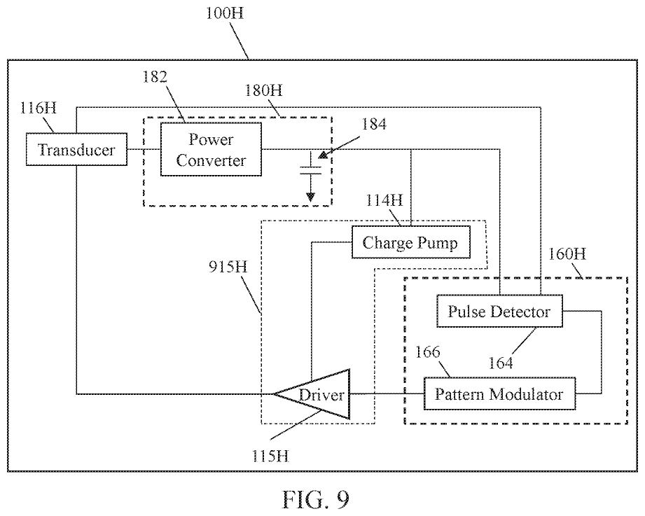

In the embodiment illustrated in FIG. 9, the contact lens 100H has a transmit path including the identification module 160H and the driver module 915H, the receive path includes the energy harvester module 180H, and the ultrasound transducer 116H is shared by components of both the transmit and receive paths. The identification module 160H in at least one embodiment encodes at least one pre-determined identification tag for transmission by the ultrasound transducer 116H. In an alternative embodiment, the ultrasound transducer 116H is replaced by a receive transducer and a transmit transducer or further by the above-described transducers.

In the embodiment illustrated in FIG. 9, the ultrasound transducer 116H is electrically connected to the energy harvester module 180H including a power converter 182 such as a voltage rectifier electrically connected to a power storage device such as the illustrated capacitor 184. In at least one embodiment, the energy harvester module is configured to receive at least one sound pressure wave having a sound pressure level of greater than approximately 1 millipascal where approximately takes into account manufacturing tolerances along with general variances from 1 millipascal. In another or further embodiment, the ultrasound module operates above approximately or greater than 20 kilohertz, or alternatively in a range of 20 kilohertz to 250 kilohertz (with a further embodiment including the end points). In other embodiments, the ultrasound transducer 116H is a piezoelectric device that converts the vibrational energy of an ultrasound “read” signal (or inquiry) into a voltage signal. In a further embodiment, the ultrasound transducer 116H is made of any piezoelectric material, that is compatible with the voltage rectifier 182 and the physical properties of the contact lens. Other example transducers include polyvinylidene fluoride or polyvinylidene difluoride (PVDF) material based transducers. One advantage of this configuration is reducing size of the system by eliminating the need for an internal power source or delaying the need to activate the internal power source.

The voltage rectifier 182 provides a rectified voltage signal output to the charge pump 114H. The charge pump 114H is electrically connected to the ultrasound transducer 116H and builds charge to provide a pulse voltage output. The power storage device 184 stores voltage output from the voltage rectifier 182 to ensure adequate voltage gain. In at least one alternative embodiment, the energy harvester 180H is put into the above-described receive paths in the ultrasound module or alternatively as a parallel circuit path that is connected through a switch to the transducer upon activation of the power supply the switch switches to the receive path.

The energy harvester 180H provides a voltage that drives the identification module 160H. The pulse detector 164 gates the identification module 160H, the driver module 915H, and the ultrasound transducer 116H. In at least one embodiment as illustrated in FIG. 9, the identification module 160H includes a pulse detector 164 and a pattern detector 166. The pulsed voltage signal output from the energy harvester module 180H corresponding to the “read” signal triggers the transmission of an identification tag. In at least one embodiment the identification tag is a unique string assigned to the contact lens. The identification tag may be any string of numbers and/or characters suitable to identify the contact lens. The pulse detector 164 provides a signal activating the pattern modulator 166. In at least one embodiment the pattern modulator 166 has the identification tag stored thereon. The pattern modulator 166 transmits a data signal embodying the identification tag to the driver module 915H, which creates a voltage signal based on the data signal from the pattern modulator 166 to drive the ultrasound transducer 116H. In at least one embodiment, the driver module 112H includes an ultrasound driver 115H and a charge pump 114H. The ultrasound transducer 116H transmits a sound pressure wave embodying the identification tag into the field of view.

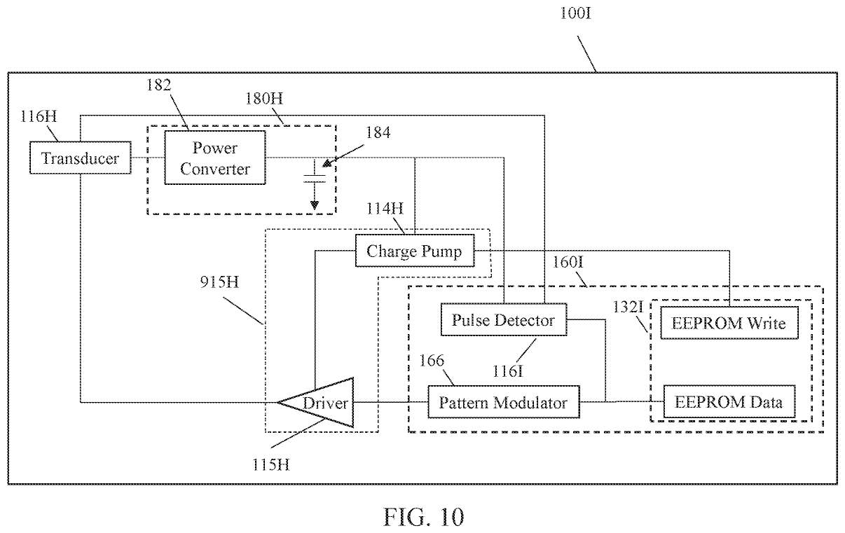

In at least one embodiment as illustrated in FIG. 10, the identification module 160I includes a data storage 132I configured to execute both a write operation to store data and a read operation to retrieve stored data. In at least one embodiment, the contact lens 100I is configured to receive a sound pressure wave embodying a message encoding an identification tag and store the decoded identification tag to the data storage 132I. This configuration provides the advantage of writing the identification tag to the data storage 132I after manufacture without the need to activate a power source. The data storage 132I is connected to the charge pump 114I of the driver module 915I, which also includes the driver 115H.

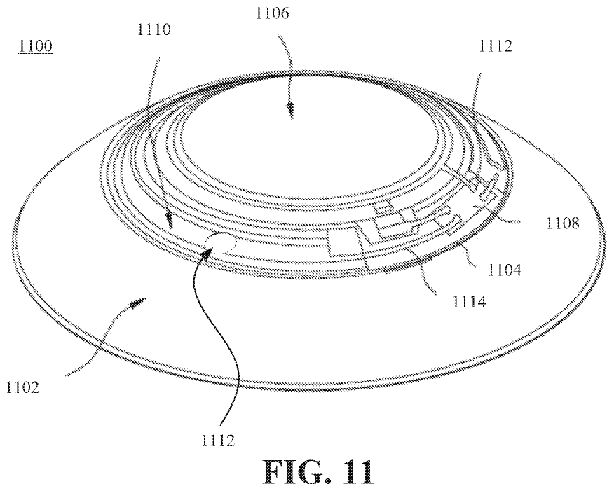

FIG. 11 illustrates a contact lens 1100 with an electronic insert 1104 having an ultrasound module. The contact lens 1100 includes a soft plastic portion 1102 which houses the electronic insert 1104, which in at least one embodiment is an electronics ring around a lens 1106. This electronic insert 1104 includes the lens 1106 which is activated by the electronics, for example focusing near or far depending on activation (or accommodation level). In at least one embodiment, the electronic insert 1104 omits the adjustability of the lens 1006. Integrated circuit 1108 mounts onto the electronic insert 1104 and connects to batteries (or power source) 1110, the lens 1106, and other components as necessary for the system.

In at least one embodiment, a transmit/receive ultrasound transducer 1112 are present in the ultrasound module. In at least one embodiment, the integrated circuit 1108 includes the transmit/receive ultrasound transducer 1112 with the associated signal path circuits. The transducer 1112 faces outward through the lens insert and away from the eye (i.e., front-facing), and is thus able to send and receive sound pressure waves. In at least one embodiment, the transducer 1112 is fabricated separately from the other circuit components in the electronic insert 1104 including the integrated circuit 1108. The transducer 1112 may also be implemented as a separate device mounted on the electronic insert 1104 and connected with wiring traces 1114. Alternatively, the transducer 1112 may be implemented as part of the integrated circuit 1108 (not shown). Based on this disclosure one of ordinary skill in the art should appreciate that transducer 1112 may be augmented by the other sensors.

In a further embodiment to the embodiment illustrated in FIG. 11, the integrated circuit 1108, the power source 1110 and the transducer 1112 are present in an area of the contact lens contained in an overmold, which is a material (such as plastic or other protective material) encapsulating the electronic insert 1104. In at least one further embodiment, the overmold encapsulates the ultrasound module(s).

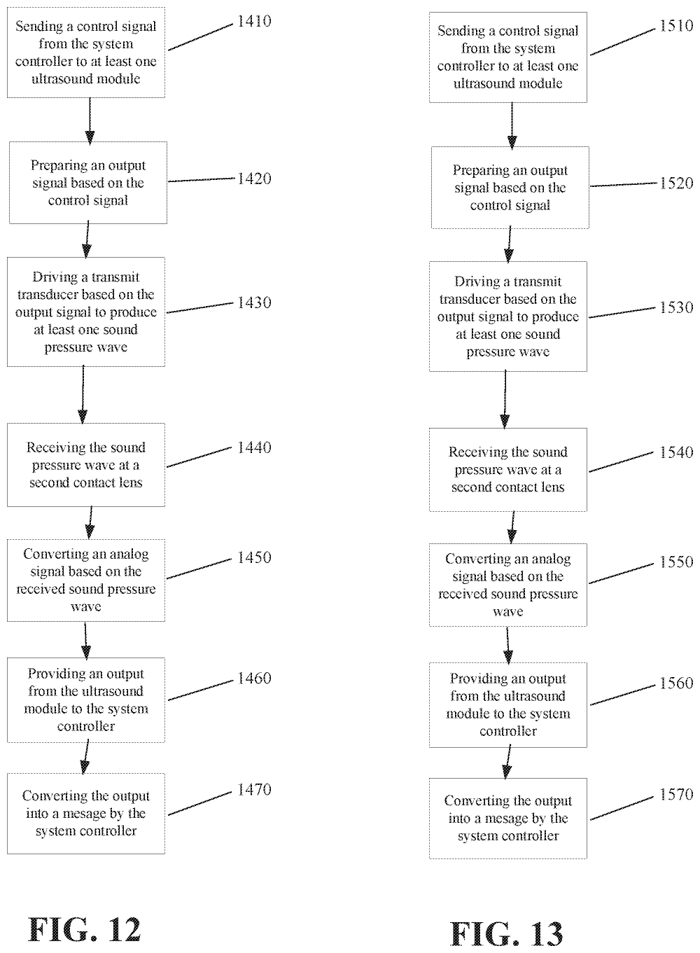

FIGS. 12 and 13 illustrate methods that may be used with more than one of the above-described system embodiments. The illustrated methods provide an example of how a contact lens configured to communicate through an ultrasound pressure wave embodying a message encoding an identification tag with an external device. In at least one embodiment, the external device could be an identification tag generator that sends the ultrasound pressure wave to the contact lens to assign the identification tag to the contact lens. The identification tag generator may include a transducer through which to communicate with the contact lens and a processor to control operation of the transducer and to generate/retrieve an identification tag, for example pursuant to a predetermined protocol or from a database accessible by the processor. The external device could be designed for this particular purpose or alternatively a smart phone with an application on it. In other embodiments, the contact lens may be providing a previously assigned identification tag to the external device, which may be for example a particular purpose device/system, a smart phone, another contact lens or another device capable of communicating using ultrasound pressure waves.

FIG. 12 illustrates an example of a method of an external device requesting the identification tag from the contact lens, 1210. In an alternative embodiment, the initial requesting step may be omitted and instead the contact lens broadcasts the identification tag on a predetermined schedule. The ultrasound transducer receives the ultrasound pressure wave embodying a read signal from an external device, 1220. The energy harvester (or energy harvester module) generates a voltage in response to the ultrasound pressure wave, 1230. The identification module activates using the voltage generated by the energy harvester, 1240. The identification module transmits a data signal representing an identification tag, 1250, and the driver module drives the ultrasound transducer to propagate a sound pressure wave embodying a message communicating the identification tag, 1260.

FIG. 13 illustrates an example of a method of assigning an identification to the contact lens. In at least one embodiment an external device propagates a sound pressure wave encoding a message embodying an identification tag, 1310. The ultrasound transducer receives the ultrasound pressure wave embodying the identification tag from an external device, 1320. The energy harvester generates a voltage in response to the ultrasound pressure wave, 1330. The identification module activates using the voltage generated by the energy harvester, 1340. The identification module decodes the message from the external device and stores the identification tag in memory, 1350.

In an alternative embodiment to the above method embodiments, the system controller facilitates communication between the identification module and the transducer and the energy harvester. In a still further embodiment, the transducer, the driver and the energy harvester are part of an ultrasound module. In another alternative embodiment, the system controller along with the data storage provide the functionality of the identification module.

One approach to facilitate the communication between the contact lens and the external device is to implement automatic frequency control for the communication channel. In at least one embodiment, the external device would be the master and communicate configuration instructions upon establishing communication protocol with the at least one contact lens. Automatic frequency control may be used to enhance the connection between the external device and the at least one contact lens. In an alternative embodiment the timing circuit on the contact lens would be the master. The clock synchronization in at least one embodiment will lead the electronics to be biased towards a lens pair to have one be a master. In a further embodiment, the selection of the master contact lens is made post-manufacturing via a software download to the lenses and/or settings change. This approach also could be used to facilitate the dual frequency approach discussed in this disclosure.

In at least one embodiment the external device initiates the configuration sequence for establishing a communication protocol with the contact lens(es). The external device transmits a start signal to the contact lens(es). In at least one embodiment, the contact lens(es) is in low power consumption mode having its transmission components deactivated and only receive components active to conserve power. This operation state may be programmed into the system controller initialization protocol. The received start signal from the external device causes each contact lens(es) to generate a random string. In embodiments the string is an 8-bit random number. The string may be used to set an 8-bit current steered digital to analog converter, which in turn sets bias current for the oscillator, i.e. the frequency, of each lens. The timing circuit clock function is tuned to the oscillator frequency. Each lens encodes the string and propagates a sound pressure wave corresponding to the string. The external device decodes the received sound pressure wave. Once the external device determines the strings from each lens are different, e.g. each lens is using a different frequency, the external device establishes communication protocol with each lens. An advantage of this embodiment is encoding two generic lenses for operation as a left lens and a right lens. The external device may be configured with specific software consistent with this method. It is understood by one of ordinary skill in the art that a suitable external device has capability to propagate sound pressure waves across the frequency band used by the ultrasound module of each contact lens.

In at least one embodiment, the energy harvester is instead a power source with the above discussed methods using power provided by the power source for operation including in at least one embodiment the detection of a query from an external source.

In at least one further embodiment to the above method embodiments, similar methods can be used for implanted intraocular lenses during use.

Although shown and described in what is believed to be the most practical embodiments, it is apparent that departures from specific designs and methods described and shown will suggest themselves to those skilled in the art and may be used without departing from the spirit and scope of the invention. The present invention is not restricted to the particular constructions described and illustrated, but should be constructed to cohere with all modifications that may fall within the scope of the appended claims.

What is claimed is:

1. An ophthalmic lens configured to provide an identification tag using ultrasound comprising:
an ultrasound module including at least one processor and at least one transducer, said ultrasound module configured to propagate and receive sound pressure waves;
a power source;
an identification module in electrical communication with said power source and said ultrasound module, said identification module having data representing an identification tag; and
wherein said ultrasound transducer is configured to receive from said identification module the data to control output of said at least one transducer.

2. The ophthalmic lens systems according to claim 1, wherein said ophthalmic lens is a contact lens.

3. The ophthalmic lens systems according to claim 1, wherein said ophthalmic lens is an intraocular lens.

4. The system according to claim 1, said identification module including a non-volatile memory having the data.

5. The system according to claim 4, wherein said non-volatile memory is at least one of an electrically erasable programmable memory, a one-time programmable memory, a magneto resistive running application memory, a ferro-magnetic running application memory, a flash memory, a read-only memory, and/or a polymer thin film ferroelectric memory.

6. The system according to claim 1, wherein said identification module further includes
an envelope detector configured to gate the identification module; and
an amplitude modulator configured to generate a digital signal embodying an identification tag.

7. The system according to claim 1, wherein
said at least one transducer includes a piezoelectric transducer; and
said power source includes an energy harvester module in electrical communication with said piezoelectric transducer, said energy harvester module having
a voltage rectifier, and
a power storage device in electrical communication with said voltage rectifier.

8. The system according to claim 7, wherein said power storage device includes a capacitor.

9. The system according to claim 7, wherein said power storage device includes a battery.

10. The system according to claim 7, wherein said power source includes an energy harvester module in electrical communication with said ultrasound module, and said energy harvester module is configured to receive at least one sound pressure wave having a sound pressure level greater than 1 millipascal.

11. The system according to claim 1, wherein said ultrasound module is configured to propagate the sound pressure wave at a frequency above 20 kilohertz.

12. The system according to claim 1, wherein said ultrasound module is configured to receive sound pressure waves at a frequency greater than 20 kilohertz.

13. The system according to claim 1, wherein said power source includes an energy harvester module; and
said identification module includes
an envelope detector in electrical communication with said energy harvester module,
an amplitude modulator in electrical communication with said envelope detector,
a non-volatile memory in electrical communication with said envelope detector and said amplitude modulator; and
wherein said ultrasound module is configured to receive from said amplitude modulator of said identification module the data to control output of said at least one transducer.

14. A method for providing an identification tag using an ophthalmic lens system including a transducer, an energy harvester, an identification module in electrical communication with the energy harvester module, and a driver module in electrical communication with the energy harvester and the identification module, the method comprising:
receiving an ultrasound pressure wave embodying a read signal from an external source by the ultrasound transducer;
generating a voltage by the energy harvester in response to the received ultrasound pressure wave;
powering the identification module with the generated voltage;
transmitting a data signal representing an identification tag for the ophthalmic lens by the identification module to the driver module; and
driving with the driver module the transducer to propagate a sound pressure wave embodying a message communicating the identification tag.

15. The method according to claim 14, wherein said identification tag includes a unique identifier for the ophthalmic lens.

16. The method according to claim 14, wherein the identification module further includes a pulse detector and a non-volatile memory configured to store and retrieve data, the method further comprising:
propagating an ultrasound pressure wave embodying an identification tag by an identification generator;
receiving the ultrasound pressure wave embodying the identification tag at the transducer of the ophthalmic lens;
generating a voltage by the energy harvester in response to the received ultrasound pressure wave embodying the identification tag;
powering the identification module in response to the received ultrasound pressure wave embodying the identification tag;
serially decoding the identification tag by the pulse detector of the identification module; and
encoding the identification tag to the non-volatile memory by the identification module.

17. The method according to claim 14, wherein the ophthalmic lens is a contact lens.

18. The method according to claim 14, wherein the ophthalmic lens is an intraocular lens.

19. A method for assigning an identification tag using an ophthalmic lens system including an ultrasound transducer, an energy harvester having a rectifier and a capacitor, an identification module including a pulse detector, a pattern modulator and a non-volatile memory configured to store and retrieve data in electrical communication with the energy harvester module, and a driver module in electrical communication with the energy harvester and the identification module, the method comprising:
propagating an ultrasound pressure wave embodying an identification tag by an identification generator;
receiving the ultrasound pressure wave embodying the identification tag at the ultrasound transducer of the ophthalmic lens;
generating a voltage by the energy harvester in response to the received ultrasound pressure wave;
powering the identification module in response to the received ultrasound pressure wave;
serially decoding the identification tag by the pulse detector of the identification module; and
encoding the identification tag to the non-volatile memory by the identification module.

20. The method according to claim 14, wherein the ophthalmic lens is a contact lens or an intraocular lens.
